(19) United States
(12) Patent Application Publication
(10) Pub. No.: US 2026/0171371 A1
(43) Pub. Date: Jun. 18, 2026

(54) SYSTEMS AND METHODS FOR INCREASING A HEAT TRANSFER CONTACT AREA ASSOCIATED WITH AN EDGE RING

(71) Applicant: LAM RESEARCH CORPORATION, Fremont, CA (US)

(72) Inventors: Chandrashekara Kaushik GANDUR BALAGANGADHARA, Bangalore (IN); Sandeep GEHANI, Raipur (IN); Michael C. KELLOGG, Oakland, CA (US); Brian Quoc HUYNH, Sunnyvale, CA (US)

(21) Appl. No.: 19/126,479

(22) PCT Filed: Oct. 30, 2023
(86) PCT No.: PCT/US2023/078244

§ 371 Date: May 1, 2025

Related U.S. Application Data
(60) Provisional application No. 63/422,380, filed on Nov. 3, 2022.

(51) Int. Cl. H01J 37/32

(52) U.S. Cl. CPC H01J 37/32642; H01J 37/32724; H01J 2237/2007

(57) ABSTRACT

Systems and methods for increasing a heat transfer contact area associated with an edge ring are described. The edge ring includes a horizontal section having an inner diameter and an outer diameter. The inner diameter surrounds a substrate receiving location of a substrate support and the horizontal section has a top surface and a lower surface. The top surface of the horizontal section faces a plasma region of the plasma chamber and the lower surface of horizontal section has an inner gel receiving section and an outer gel receiving section. The inner gel receiving section is in thermal contact with the substrate support and the outer gel receiving section is in thermal contact with a coupling ring. The edge ring further includes a vertical extension extending from the horizontal section. The vertical extension is oriented downward at the outer diameter of the horizontal section.

### FIELD

The present embodiments relate to systems and methods for increasing a heat transfer contact area associated with an edge ring.

### BACKGROUND

In a plasma tool, a plasma chamber is provided in addition to other components, such as a radio frequency (RF) generator and an impedance matching circuit. The plasma chamber includes an upper electrode, a substrate support, and multiple rings that are associated with the substrate support. The upper electrode is located above the substrate support and the rings. A wafer is placed on top of the substrate support for processing. It is important that the components including the rings be provided to increase an efficiency of processing the wafer.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

Embodiments of the disclosure provide systems, apparatus, methods and computer programs for increasing a heat transfer contact area associated with an edge ring. It should be appreciated that the present embodiments can be implemented in numerous ways, e.g., a process, an apparatus, a system, a device, or a method on a computer readable medium. Several embodiments are described below.

In an embodiment, dielectric tools use pull-down clamp mechanisms, such as pull-down rods, in a bias assembly for holding an edge ring against a shoulder of an electrostatic chuck (ESC) with thermal interface gels sandwiched between them. A heat transfer path through these gels is important because of heat sink location being within a baseplate of the ESC. The heat transfer in a gel interface region is directly proportional to pressure applied by the clamp mechanisms and compression of the gels, thermal conductivity of the gels and the overall gel contact area. This gel surface contact area is a direct function of deformation, such as deflection, of the edge ring, hardness of the gels, load applied to the clamp mechanisms, and thermal expansion of the edge ring and the gels.

In an embodiment, an edge ring is described. The edge ring includes a horizontal section having an inner diameter and an outer diameter. The inner diameter surrounds a substrate receiving location of a substrate support and the horizontal section has a top surface and a lower surface. The top surface of the horizontal section faces a plasma region of the plasma chamber and the lower surface of horizontal section has an inner gel receiving section and an outer gel receiving section. The inner gel receiving section is in thermal contact with the substrate support and the outer gel receiving section is in thermal contact with a coupling ring. The edge ring further includes a vertical extension extending from the horizontal section. The vertical extension is oriented downward at the outer diameter of the horizontal section. Also, the vertical extension provides an anchor for reducing flex of the horizontal section when a thermal gel is placed at each of the inner gel receiving section and the outer receiving section.

In one embodiment, an edge ring is described. The edge ring includes a main body having a top portion, an inner portion contiguous with the top portion, a bottom portion contiguous with the inner portion, and a first outer surface contiguous with the top portion. The edge ring has a vertical extension. The vertical extension has a second outer surface contiguous with the first outer surface. The vertical extension has an annular shape extending from a level of the bottom portion to a pre-determined level located below the level of the bottom portion. The vertical extension extends to the pre-determined level at an outer diameter of the top portion.

In an embodiment, a plasma chamber is described. The plasma chamber includes a top electrode, and an ESC located below the top electrode to form a plasma region there between. The ESC has a top portion and a bottom portion. The plasma chamber has an edge ring located besides the ESC and a coupling ring located below the edge ring. The edge ring includes a horizontal section having an inner diameter and an outer diameter. The inner diameter surrounds the top portion of the ESC, and the horizontal section has a top surface and a lower surface. The lower surface of horizontal section has an inner gel receiving section and an outer gel receiving section. The inner gel receiving section is in thermal contact with the ESC and the outer gel receiving section is in thermal contact with the coupling ring. The edge ring includes a vertical extension extending from the horizontal section. The vertical extension is oriented downward at the outer diameter of the horizontal section. Also, the vertical extension provides an anchor for reducing flex of the horizontal section when a thermal gel is placed at each of the inner gel receiving section and the outer receiving section.

Some advantages of the herein described systems and methods, described herein, include increasing the gel contact area through reduction in deformation of the edge ring. For example, a topology of the edge ring is modified to increase the gel contact area. To illustrate, a vertical extension is integrated or affixed to the edge ring to increase the gel contact area. To further illustrate, the vertical extension increases a stiffness of the edge ring. The increase in the stiffness results in a lower amount of deformation of a main body of the edge ring, and the lower amount of deformation results in an increased contact area between an inner gel and an outer top surface of the ESC. The increase in the contact area causes a higher heat transfer area to achieve an increased thermal performance of transferring heat from plasma to a heat sink in the baseplate. The increased thermal performance results in reduced temperatures of the edge ring and the gels increasing a lifespan of the gels. Also, the increased thermal performance provides an additional temperature buffer for high power processes and an increase in power per unit area handled by components of a plasma chamber. Moreover, the increased thermal performance reduces a need for additional applications to increase pressure to be applied to the inner gel.

Other aspects will become apparent from the following detailed description, taken in conjunction with the accompanying drawings.

### BRIEF DESCRIPTION OF THE DRAWINGS

The embodiments may best be understood by reference to the following description taken in conjunction with the accompanying drawings.

FIG. 1 is a diagram of an embodiment of the system to illustrate use of an edge ring with an inner gel.

FIG. 2A is a diagram of an embodiment of an edge ring to illustrate a shape of a vertical extension of the edge ring.

FIG. 2B is a diagram of an embodiment of an edge ring to illustrate a dimension of a vertical extension of the edge ring that is different from dimension of the vertical extension of FIG. 2A.

FIG. 2C is a diagram of an embodiment of an edge ring to illustrate a vertical extension having a trapezoidal cross-section along x and y axes.

FIG. 2D is a diagram of an embodiment of an edge ring to illustrate a dimension of a vertical extension that is different than a dimension of the vertical extension of FIG. 2C.

FIG. 3 is an isometric bottom view of an embodiment of an edge ring.

FIG. 4A is a top view of an edge ring without a vertical extension.

FIG. 4B is a side view of an embodiment of the edge ring of FIG. 4A to illustrate that there are many discrepancies in contact between a bottom surface of a section of the edge ring of FIG. 4A and an outer top surface of a substrate support via an inner gel when the vertical extension is not implemented.

FIG. 5 is an embodiment of a graph to illustrate a relationship between a percentage of contact area between the inner gel and an edge ring having a vertical extension compared to a relationship between a percentage of contact area between the inner gel and the edge ring of FIG. 4A.

FIG. 6 is a diagram of an embodiment of a system to illustrate that an effect on plasma created by any possible erosion of an edge ring, described herein, having a vertical extension can be compensated by controlling radio frequency (RF) power supplied to the edge ring.

FIG. 7A is a diagram of an embodiment of another edge ring having a vertical extension.

FIG. 7B is a diagram of an embodiment of yet another edge ring having a vertical extension.

### DETAILED DESCRIPTION

The following embodiments describe systems and methods for increasing a heat transfer contact area associated with an edge ring. It will be apparent that the present embodiments may be practiced without some or all of these specific details. In other instances, well known operations have not been described in detail in order not to unnecessarily obscure the present embodiments.

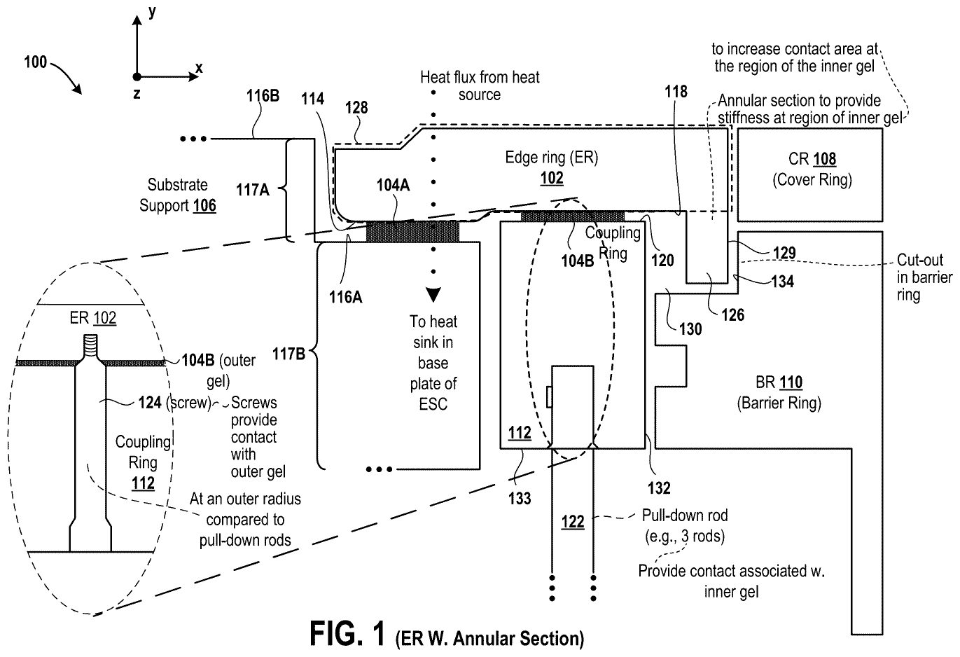

FIG. 1 is a diagram of an embodiment of the system 100 to illustrate use of an edge ring (ER) 102 with an inner gel 104A. The system 100 includes a substrate support 106, such as an electrostatic chuck (ESC) having a base plate. The system 100 further includes a cover ring (CR) 108, a barrier ring (BR) 110, and a coupling ring 112. The coupling ring 112 is sometimes referred to herein as a support ring. The edge ring 102 is fabricated from a material, such as, silicon (Si), or Quartz, or Silicon Carbide (SiC). The cover ring 108 is fabricated from a dielectric material, such as fused silica-Quartz, or a ceramic material, such as, aluminum oxide (Al₂O₃) or Yttrium oxide (Y₂O₃). The barrier ring 110 is fabricated from a material, such as Quartz. The coupling ring 112 is made from a dielectric material, such as quartz, or ceramic, or alumina (Al₂O₃), or a polymer. Each ring, described herein, has an annular body, such as a circular body, or a ring-shaped body, or a disc-shaped body.

The edge ring 102 is placed besides the substrate support 106. For example, an inner diameter of the edge ring 102 radially surrounds a diameter of a top portion 117A of the substrate support 106. As an example, the top portion 117A is a head of the substrate support 106. The coupling ring 112 radially surrounds a bottom portion 117B of the substrate support 106. The bottom portion 117B is sometimes referred to herein as an ESC shoulder. The bottom portion 117B is located below the top portion 117A and is contiguous with the top portion 117A. As an example, two portions, such as a first portion and a second portion, are contiguous with respect to each other when there is no space or gap between the two portions and the second portion provides continuity to the first portion.

Moreover, the cover ring 108 radially surrounds a top portion, including a main body 128, of the edge ring 102 and the barrier ring 110 surrounds a bottom portion of the edge ring 102. The main body 128 is outlined and surrounded using dashed lines in FIG. 1. The bottom portion of the edge ring 102 includes a vertical extension 126 of the edge ring 102. The barrier ring 110 also surrounds the coupling ring 112 and is located below the cover ring 108. The coupling ring 112 is located radially between the substrate support 106 and the barrier ring 110.

The inner gel 104A is applied to an inner bottom surface 114 of the edge ring 102 and to an outer top surface 116A of the bottom portion 117B of the substrate support 106. The outer top surface 116A is a step down from an inner top surface 116B of the top portion 117A of the substrate support 106. Moreover, an outer gel 104B is applied to a middle bottom surface 118 of the edge ring 102 and to a top surface 120 of the coupling ring 112. As such, the inner gel 104A provides an interface or a contact between the inner bottom surface 114 and the outer top surface 116A, and the outer gel 104A provides an interface or a contact between the middle bottom surface 118 and the top surface 120. The inner bottom surface 114 is radially closer, along an x-axis, to the substrate support 106 compared to the middle bottom surface 118. For example, the inner bottom surface 114 is closer to the inner top surface 116B than the middle bottom surface 118.

Also, an insulator ring (not shown) is located below and adjacent to the coupling ring 112. The coupling ring 112 is coupled, such as attached or fitted, to the edge ring 102 via multiple screws, such as a screw 124. Multiple pull-down rods, such as a pull-down rod 122, are coupled to an underside, such as a bottom surface 133, of the coupling ring 112. For example, multiple holes extend from the bottom surface 133 into the coupling ring 112 in a vertical direction, such as a +y direction. The pull-down rods are inserted into the holes to extend in the +y direction within the coupling ring 112.

The pull-down rods are simultaneously raised, in the vertical direction, such as the +y direction, to simultaneously raise the coupling ring 112 and the edge ring 102 with respect to the insulator ring (not shown) to remove the coupling ring 112 and the edge ring 102 from a plasma chamber, illustrated below. Moreover, the pull-down rods are simultaneously pulled downwards, in a vertical direction, such as a −y direction, to pull-down the coupling ring 112 and the edge ring 102 simultaneously with respect to the insulator ring (not shown). The screws increase an amount of contact area between the middle bottom surface 118 of the edge ring 102 and the outer gel 104B and between the top surface 120 of the coupling ring 112 and the outer gel 104B.

Each of the y direction and the −y direction are measured along, such as parallel to, a y-axis, which is perpendicular to the x-axis. Each of the x-axis and the y-axis is perpendicular to a z-axis. The y direction is opposite to the −y direction along the y-axis.

When there is thermal contact between the inner bottom surface 114 of the edge ring 102 via the inner gel 104A with the outer top surface 116A of the substrate support 106, the base plate of the substrate support 106 provides a heat sink. For example, due to the thermal contact, heat flows from plasma within the plasma chamber via the main body 128, the inner bottom surface 114 of the edge ring 102, the inner gel 104A, the outer top surface 116A of the substrate support 106, and the top portion 117B to the heat sink within the base plate. The greater the contact area between the edge ring 102 and the inner gel 104A and between the outer top surface 116A of the substrate support 106 and the inner gel 104A, the greater an amount of the thermal contact between the inner bottom surface 114 and the outer top surface 116A of the substrate support 106. The greater amount of thermal contact enables a greater an amount of heat flow from the plasma to the heat sink. An example of the heat sink is a coolant or a cooling gas, such as helium.

Moreover, there is thermal contact between the middle bottom surface 118 of the edge ring 102 and the top surface 120 of the coupling ring 112 via the outer gel 104B. The thermal contact between the middle bottom surface 118 of the edge ring 102 and the top surface 120 of the coupling ring 112 is achieved with the screws. The screws increase contact area between the outer gel 104B and the middle bottom surface 118 of the edge ring 102 and increase contact area between the outer gel 104B and the top surface 120 of the coupling ring 112. The increase in the contact areas increase thermal contact between the middle bottom surface 118 of the edge ring 102 and the top surface 120 of the coupling ring 112.

The edge ring 102 has the vertical extension 126 that extends vertically downward, in the −y direction, from the main body 128 of the edge ring 102. For example, the vertical extension 126 is at an outer edge of the edge ring 102 and has an outer surface 129 that is the same as the outer surface 129 of the main body 128. As an illustration, the vertical extension 126 or any other vertical extension, described herein, is machined from silicon ingots or chemical vapor deposition (CVD) Silicon Carbide (SiC) blanks. As another illustration, the vertical extension 126 or any other vertical extension, described herein, is fabricated from compression molding or slip casting. As another example, the vertical extension 126 and the main body 128 are one unitary body. To further illustrate, an edge ring, described herein, having a main body and a vertical extension integrally formed with the main body is fabricated by a molding machine. In the further illustration, the molding machine has the shape of the edge ring 102 having the vertical extension 126. In the further illustration, the vertical extension is integrally formed with the main body when the vertical extension is integrated with the main body to form one unitary body, such as one unitary piece, of the edge ring. In the further illustration, when the vertical extension is integrated with the main body, there are no screws or other attachments to attach the vertical extension to the main body. In the further illustration, the material for fabricating the edge ring is placed in the molding machine and is treated, such as heated and annealed, to fabricate the edge ring. As another illustration, an outer surface of a vertical extension of an edge ring is contiguous with, such as is continuous with, an outer surface of a main body of the edge ring. In the illustration, the vertical extension is oriented, such as extends, downward at an outer diameter of the outer surface of the main body. It should be noted that as an example, two surfaces, such as a first surface and a second surface, are contiguous with respect to each other when there is no space or gap between the two surfaces and the second surface provides continuity to the first surface.

As another example of the vertical extension 126 extending vertically downward from the main body 128 of the edge ring 102, the vertical extension 126 is coupled to the main body 128. An illustration of coupling the vertical extension 126 to the main body 128 includes attaching the vertical extension 126 to the main body 128 with screws. To further illustrate, a main body of an edge ring, described herein, is fabricated by a first molding machine, and a vertical extension coupled to the main body is fabricated by a second molding machine. In the further illustration, the material for fabricating the main body is placed in the first molding machine and is treated, such as heated and annealed, to fabricate the edge ring. Also, in the further illustration, the material for fabricating the vertical extension is placed in the second molding machine and is treated, such as heated and annealed, to fabricate the vertical extension. In the further illustration, the vertical extension is then coupled to the main body to fabricate the edge ring.

The vertical extension 126 has an annular shape, such as a ring shape or a disc shape. The vertical extension 126 extends within a space 130, such as a gap or a groove, formed between the coupling ring 112 and the barrier ring 110. A width of the space 130 is greater than a width of the vertical extension 126 to accommodate vertical extensions of different widths within the space 130. For example, the space 130 accommodates the vertical extension 126. Moreover, the space 130 is wide enough to accommodate another vertical extension that is wider, along the x-axis, compared to the vertical extension 126. A width, as used herein, is measured along the x-axis.

The barrier ring 110 is fabricated to form the space 130. For example, the barrier ring 110 lacks a top left corner as viewed in an xy-plane formed between the x-axis and the y-axis. The space 130 is formed between an outer surface 132 at an outer edge of the coupling ring 112 and an inner surface 134 at an inner edge of a top portion of the barrier ring 110.

The vertical extension 126 increases stiffness of the main body 128 to further increase a contact area between the inner gel 104A and the inner bottom surface 114 and a contact area between the inner gel 104A and the outer top surface 116A. For example, there is 90 to 100 percent contact between the inner gel 104A and the inner bottom surface 114 and 90 to 100 percent contact between the inner gel 104A and the outer top surface 116A.

A vertical extension, described herein, provides an anchor for reducing flex, such as bending or curvature or wavy shape, along a circumference of the main body 128 when the inner gel 104A and the outer gel 104B are used and a clamping force is applied by the screws and the pull-down rods. The clamping force is applied when the pull-down rods pull down the coupling ring 112 and the clamping force results in a compression of the inner gel 104A to increase the contact areas associated with the inner gel 104A.

In an embodiment, a main body of an edge ring is sometimes referred to herein as a horizontal section of the edge ring.

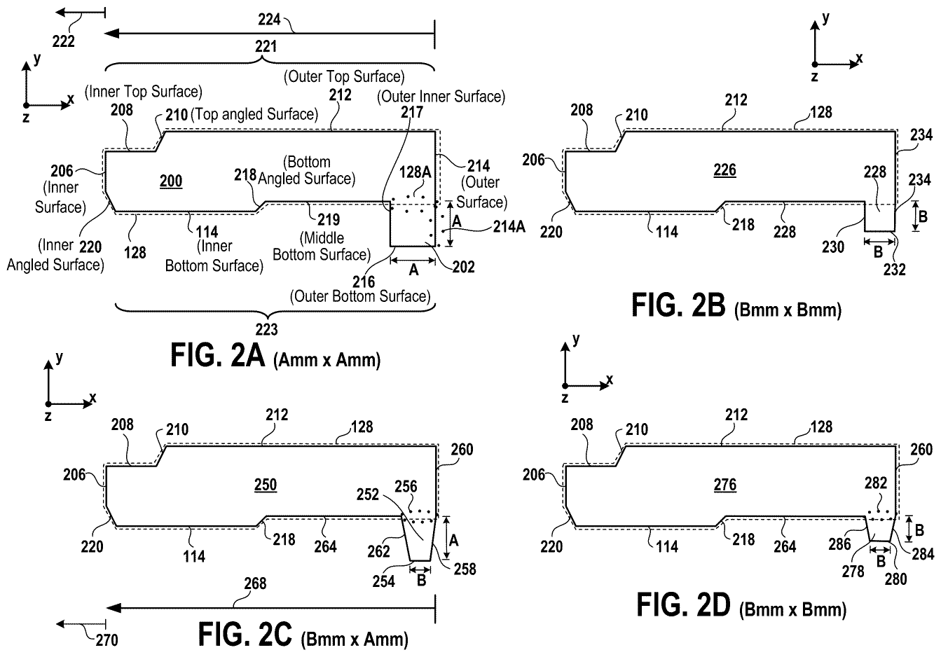

FIG. 2A is a diagram of an embodiment of an edge ring 200 to illustrate a shape and size of a vertical extension 202 of the edge ring 200. The edge ring 200 includes the main body 128 and the vertical extension 202. The edge ring 200 is used in place of the edge ring 102 (FIG. 1). For example, the vertical extension 202 extends into the space 130 (FIG. 1).

The main body 128 includes an inner surface 206, an inner top surface 208, a top angled surface 210, an outer top surface 212, an outer surface 214, an outer bottom surface 216, an outer inner surface 217, a middle bottom surface 219, a bottom angled surface 218, the inner bottom surface 114, and an inner angled surface 220.

A combination of the inner top surface 208, the top angled surface 210, and the outer top surface 212 of an edge ring, described herein, is sometimes referred to herein as a top portion, such as a top surface 221, of the edge ring. Moreover, a combination of the inner surface 206 and the inner angled surface 220 of an edge ring, described herein, is sometimes referred to herein as an inner portion of the edge ring. Also, a combination of the inner bottom surface 128, the bottom angled surface 218, and a middle bottom surface, described herein, of an edge ring, described herein, is sometimes referred to herein as a bottom portion of the edge ring. An example of the bottom portion of the edge ring is a lower surface of the main body 128. To illustrate, a combination of the inner bottom surface 128, the bottom angled surface 218, and the middle bottom surface 219 is sometimes referred to herein as a lower surface 223 of the main body 128. A combination of an outer surface of the main body 128, an outer surface of a vertical extension of an edge ring, described herein, an outer bottom surface of the vertical extension, and an outer inner surface of the vertical extension is sometimes referred to herein as an outer portion of the edge ring.

The top portion of an edge ring, described herein, is adjacent, such as next to, the inner portion of the edge ring. For example, the inner top surface 208 is next to or contiguous with the inner surface 206. Also, the bottom portion of an edge ring, described herein, is adjacent to the inner portion of the edge ring. For example, the inner bottom surface 128 is next to the inner angled surface 220. The outer portion of an edge ring, described herein, is adjacent to the top and bottom portions of the edge ring. For example, the outer surface of the main body 128 is next to the outer top surface 212. Also, in the example, outer surface of the main body 128 is next to the outer surface of the vertical extension. Further, in the example, the outer inner surface of the vertical extension is next to and contiguous with the middle bottom surface of the edge ring.

A vertical extension of an edge ring, described herein, forms an annular section, such as a disc-shaped section or a ring-shaped section, that extends from a horizontal level, along the x-axis, of the bottom portion of the edge ring to a pre-determined level located below the horizontal level to form the outer portion of the edge ring. The pre-determined level is a horizontal level located along the x-axis and below the level of the bottom portion of the edge ring. An example of the pre-determined level is a height of A mm or B mm in the −y direction from the horizontal level of the middle bottom surface of the main body 128.

The inner bottom surface 114 is sometimes referred to herein as an inner gel receiving section and a middle bottom surface, described herein, of an edge ring is sometimes referred to herein as an outer gel receiving section. For example, the middle bottom surface 219 is sometimes referred to herein as the outer gel receiving section.

The main body 128 of the edge ring 200 is the same as the main body 128 of the edge ring 102 (FIG. 1) except that the main body 128 of the edge ring 200 includes the middle bottom surface 219. The middle bottom surface 219 has a smaller width compared to a width of the middle bottom surface 118 (FIG. 1) of the edge ring 102. This is because the vertical extension 202 is wider than the vertical extension 126 (FIG. 1).

The inner surface 206 is a vertically oriented surface. The inner top surface 208 is a horizontally oriented surface, and forms an obtuse angle that is greater than 90° but less than 180° with respect to the top angled surface 210. The top angled surface 210 forms an angle greater than 180° and less than 270° with respect to the outer top surface 212. Also, the outer top surface 212 is a horizontally oriented surface and the outer surface 214 is a vertically oriented surface. The outer bottom surface 216 is a horizontally oriented surface, the outer inner surface 217 is a vertically oriented surface, and the middle bottom surface 219 is a horizontally oriented surface. Also, the inner bottom surface 114 forms an obtuse angle, which is greater than 90° and less than 180°, with respect to the bottom angled surface 218. The bottom angled surface 218 forms an angle greater than 180° and less than 270° with respect to the middle bottom surface 219. The bottom angled surface 218 provides an upward transition, such as a step up, from the inner bottom surface 114 to the middle bottom surface 219. For example, a horizontal level of the middle bottom surface 219 is greater than a horizontal level of the inner bottom surface 114. A horizontal level, as described herein, is measured along the x-axis.

The inner bottom surface 114 is a horizontally oriented surface and the inner angled surface 220 forms an obtuse angle, such as one greater than 90° and less than 180°, with respect to the inner bottom surface 114. Also, the inner surface 206 forms an obtuse angle that is greater than 90° but less than 180° with respect to the inner angled surface 220. As an example, a vertically oriented surface, as described herein, extends in the +y-direction or the −y-direction. Moreover, as an example, a horizontally oriented surface, described herein, extends in a +X-direction or a −x-direction. The x-direction and the −x-direction are measured along the x-axis. The x direction is opposite to the −x direction along the x-axis.

The inner top surface 208 is contiguous with the inner surface 206, the top angled surface 210 is contiguous with the inner top surface 208, and the outer top surface 212 is contiguous with the top angled surface 210. Moreover, the outer surface 214 is contiguous with the outer top surface 212, the outer bottom surface 216 is contiguous with the outer surface 214, the outer inner surface 217 is contiguous with the outer bottom surface 216, and the middle bottom surface 219 is contiguous with the outer inner surface 217. Also, the bottom angled surface 218 is contiguous with the middle bottom surface 219, the inner bottom surface 114 is contiguous with the bottom angled surface 218, the inner angled surface 220 is contiguous with the inner bottom surface 114, and the inner surface 206 is contiguous with the inner angled surface 220.

The vertical extension 202 is bound by the outer bottom surface 216, a portion 214A of the outer surface 214 extending to the main body 128, a portion 128A of the main body 128, and the outer inner surface 217. For example, the vertical extension 202 interfaces with and is adjacent to the main body 128 at the portion 128A of the main body 128. To illustration, the portion 128A is also a top surface of the vertical extension 202. In the illustration, the top surface of the vertical extension 202 is integrated with the portion 128A of the main body 128. As such, in the illustration, the top surface of the vertical extension 202 is not exposed to a space or a gap.

The vertical extension 202 has a dimension of A millimeters (mm)×A mm as measured along the x-axis and the y-axis. For example, a height of the vertical extension 202 is A mm and a width of the vertical extension 202 is A mm. An example of A mm is a number within a range from and including 5 mm to 6 mm. To illustrate, A is 5 mm or 6 mm. To further illustrate, a vertical extension, as described herein, has a square cross-section or a rectangular cross-section taken along the x-axis and the y-axis. A height, as described herein, is measured along the y-axis. The dimension of A×A mm is an example of a cross-sectional area of the vertical extension 202.

The vertical extension 202 has a width that extends from the outer surface 214 to the middle bottom surface 219. Also, the width of the vertical extension 202 is less than a width of the middle bottom surface 219.

Each edge ring, described herein, has an inner diameter of an inner surface and an outer diameter of an outer surface of the edge ring. For example, the edge ring 200 has an inner diameter 222 and an outer diameter 224. The inner diameter is a diameter of the inner surface 206 and the outer diameter 224 is a diameter of the outer surface 214. The inner diameter of the edge ring surrounds a substrate receiving location, which is a space within a plasma chamber. At the substrate receiving location, the substrate support 106 (FIG. 1) is received. For example, at the substrate receiving location, the top portion 117A is received. The inner diameter of the edge ring is adjacent to a diameter of the top portion 117A of the substrate support 106 (FIG. 1).

A vertical extension, as described herein, of an edge ring has a width that is less than a width of the main body 128. For example, a width of an outer bottom surface of the edge ring is less than a width of the top surface of the main body 128. In the example, the width of the top surface of the main body 128 is equal to the width of the main body 128. As an illustration, the width of the main body 128 is a difference between the outer diameter 224 and the inner diameter 222. As another example, a width of the vertical extension 202 is less than a width of the middle bottom surface 218 and a width of the inner bottom surface 114.

Also, a width of the vertical extension does not add to a width of the top surface of the main body 128. For example, the vertical extension does not extend from an outer surface of the main body 128, described herein, along the x-axis, in the +x-direction but rather extends from the outer surface main body 128 in the −x-direction, such as towards the bottom angled surface 218.

In one embodiment, the inner bottom surface 114 is above or below a horizontal level, along the x-axis, of the middle bottom surface 219. In an embodiment, the inner bottom surface 114 extends in a horizontal direction, along the x-axis, until the outer inner surface 217 is reached. For example, the middle bottom surface 219 and the inner bottom surface 114 are not separated by the bottom angled surface 218 to form one contiguous surface, which lies in a single horizontal plane along the x-axis. In one embodiment, the inner bottom surface 114 has one or more grooves to accommodate respective one or more vacuum seals between the inner bottom surface 114 and the outer top surface 116A (FIG. 1) of the substrate support 106.

FIG. 2B is a diagram of an embodiment of an edge ring 226 to illustrate a dimension of a vertical extension 228 of the edge ring 200 (FIG. 2A) that is different from the dimension of the vertical extension 202 (FIG. 2A). For example, the vertical extension 228 has a dimension of B mm×B mm as measured along the x-axis and the y-axis. For example, a height of the vertical extension 228 is B mm and a width of the vertical extension 228 is B mm. For example, the B mm height is a number within a range from and including 2 mm to 6 mm. To illustrate, the B mm height is 2 mm or 5 mm or 6 mm. As another example, the B mm width is a number within a range from and including 2 mm to 2.5 mm. To illustrate, the B mm width is 2 mm or 2.5. The dimension of B×B mm is an example of a cross-sectional area of the vertical extension 228. The edge ring 226 is used in place of the edge ring 102 (FIG. 1). For example, the vertical extension 228 extends into the space 130 (FIG. 1).

Moreover, all surfaces of the main body 128 of the edge ring 226 are the same as the surfaces of the main body 128 of the edge ring 200 except the middle bottom surface 219 (FIG. 2A). The main body 128 has a middle bottom surface 228 instead of the middle bottom surface 219. The middle bottom surface 228 is wider than the middle bottom surface 219 because the vertical extension 228 is less wide compared to a width of the outer bottom surface 216.

In addition to the surfaces 206, 208, 210, 212, 220, 114, and 218, the edge ring 226 has the middle bottom surface 228, an outer inner surface 230, an outer bottom surface 232, and an outer surface 234. The middle bottom surface 228 is horizontally oriented, the outer inner surface 230 is vertically oriented, the outer bottom surface 232 is horizontally oriented, and the outer surface 234 is vertically oriented. Also, the middle bottom surface 228 is contiguous with the bottom angled surface 218, the outer inner surface 230 is contiguous with the middle bottom surface 228, the outer bottom surface 232 is contiguous with the outer inner surface 230, the outer surface 234 is contiguous with the outer bottom surface 232, and the outer top surface 212 is contiguous with the outer surface 214. The bottom angled surface 218 forms an angle greater than 180° and less than 270° with respect to the middle bottom surface 228.

FIG. 2C is a diagram of an embodiment of an edge ring 250 to illustrate an edge ring 250 having a vertical extension 252. The vertical extension 252 has a trapezoidal cross-section along the x and y axes. For example, the vertical extension 252 has an outer bottom surface 254 that is less wide than a top surface 256 of the vertical extension 252. In the example, the top surface 256 of the vertical extension 252 is integrated with a portion of the main body 128. As such, in the example, the top surface 256 is not exposed to a space or a gap. To illustrate, the outer bottom surface 254 is B mm wide. The edge ring 250 is used in place of the edge ring 102 (FIG. 1). For example, the vertical extension 252 extends into the space 130 (FIG. 1).

The edge ring 250 includes the main body 128 and the vertical extension 252. The vertical extension 252 has a dimension of A×B mm and a height of A mm. The dimension of A×B mm is an example of a cross-sectional area of the vertical extension 252. The vertical extension 252 has an outer surface 258, which is obliquely located, such as obliquely oriented, with respect to the outer bottom surface 254. For example, the outer surface 258 forms an angle that is greater than 90° but less than 180° with respect to an outer surface 260 of the main body 128 of the edge ring 250. Also, in the example, the outer bottom surface 254 forms an obtuse angle with reference to the outer surface 258. The outer surface 260 is vertically oriented and the outer bottom surface 254 is horizontally oriented. Moreover, the vertical extension 252 has an outer inner surface 262, which is obliquely located, such as obliquely oriented, with respect to the outer bottom surface 254. For example, the outer inner surface 262 forms an obtuse angle with respect to the outer bottom surface 254.

The main body 128 has a middle bottom surface 264. The bottom angled surface 218 forms an angle that is greater than 270° and less than 360° with respect to the middle bottom surface 264. Also, the middle bottom surface 264 forms an angle that is greater than 180° but less than 270° with respect to the middle bottom surface 264.

The outer surface 258 is contiguous with the outer surface 260, which is contiguous with the outer top surface 212. Also, the outer bottom surface 254 is contiguous with the outer surface 258 and the outer inner surface 262 is contiguous with the outer bottom surface 254.

The edge ring 250 has an outer diameter 268 and an inner diameter 270. The inner diameter 270 is a diameter of the inner surface 206 and the outer diameter 270 is a diameter of the outer surface 260.

FIG. 2D is a diagram of an embodiment of an edge ring 276 to illustrate a dimension of a vertical extension 278 that is different than a dimension of the vertical extension 252 (FIG. 2C). The vertical extension 278 of the edge ring 276 also has a trapezoidal cross-section along the x and y axes. For example, the vertical extension 278 has an outer bottom surface 280 that is less wide compared to a top surface 282 of the vertical extension 278. The edge ring 276 is used in place of the edge ring 102 (FIG. 1). For example, the vertical extension 278 extends into the space 130 (FIG. 1).

A height of the vertical extension 278 is less than the height of the vertical extension 252 (FIG. 2C). For example, the height of the vertical extension 278 is B mm. The vertical extension 278 has a dimension of B×B mm. The dimension of B×B mm is an example of a cross-sectional area of the vertical extension 278.

The edge ring 276 includes the main body 128 and the vertical extension 278. The vertical extension 278 has an outer surface 284, which is obliquely located, such as obliquely oriented, with respect to the outer bottom surface 280. For example, the outer surface 284 forms an angle that is greater than 270° but less than 360° with respect to the outer surface 260 of the main body 128 of the edge ring 276. Also, in the example, the outer bottom surface 280 forms an obtuse angle with reference to the outer surface 284.

The outer bottom surface 280 is horizontally oriented. Moreover, the vertical extension 278 has an outer inner surface 286, which is obliquely located with respect to the outer bottom surface 280. For example, the outer inner surface 286 forms an obtuse angle with respect to the outer bottom surface 280. The middle bottom surface 264 forms an angle that is greater than 180° and less than 270° with respect to outer inner surface 286.

The outer surface 284 is contiguous with the outer surface 260. Also, the outer bottom surface 280 is contiguous with the outer surface 284 and the outer inner surface 286 is contiguous with the outer bottom surface 280.

It should be noted that an outer bottom surface, such as the outer bottom surface 280, of a vertical extension, described herein, of an edge ring is at a lower horizontal level than a horizontal level of a bottom surface of the main body 128 of the edge ring. For example, the outer bottom surface 280 is at a lower horizontal level, along the x-axis, than a horizontal level, also measured along the x-axis, of the inner bottom surface 114. The horizontal level of the inner bottom surface 114 is lower than a horizontal level, along the x-axis, of a middle bottom surface of the edge ring.

Also, the coupling ring 112 (FIG. 1) is located at a horizontal level below a horizontal level of the bottom surface of the main body 128 of an edge ring but not below a horizontal level of the outer bottom surface of a vertical extension of the edge ring. The outer surface 132 (FIG. 1)

It should further be noted that a vertical extension of an edge ring, described herein, and the main body 128 form a L-shape as viewed in the xy-plane formed between the x-axis and the y-axis. For example, the vertical extension 278 and the main body 128 forms the L-shape. As another example, the vertical extension 202 (FIG. 2A) and the main body 128 forms an L-shape.

It should also be noted that a vertical extension, described herein, can be used with any other main body (not shown) having a shape or size or a combination thereof different from a shape or a size or a combination thereof of the main body 128. The vertical extension is used with the other main body to form another edge ring (not shown). For example, the vertical extension is integrated with or coupled to the other main body (not shown) that lacks the bottom angled surface 218 or the inner angled surface 220 or the top angled surface 210 or a combination thereof. To illustrate, when the other main body (not shown) lacks the bottom angled surface 220, the inner bottom surface 128 of the other main body (not shown) is contiguous with a middle bottom surface, described herein, of the other main body (not shown). Also, in the illustration, when the other main body (not shown) lacks the inner angled surface 220, the inner surface 206 of the other main body (not shown) is contiguous with the inner bottom surface 114 of the other main body (not shown). Further, in the illustration, when the other main body (not shown) lacks the top angled surface 210, the inner top surface 208 of the other main body (not shown) is contiguous with the outer top surface 212 of the other main body (not shown).

In an embodiment, any of the edge rings 226 (FIGS. 2B), 250 (FIG. 2C), and 276 is used in place of the edge ring 102 in the system 100 (FIG. 1).

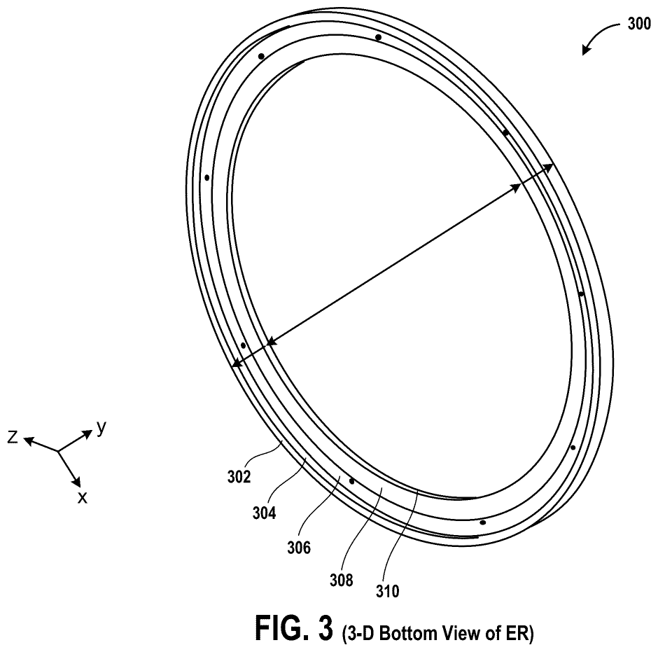

FIG. 3 is an isometric bottom view of an embodiment of an edge ring 300. The edge ring 300 has an annular shape, such as a shape of a disc. The edge ring 300 has an outer bottom surface 302, an outer inner surface 304, a middle bottom surface 306, an inner bottom surface 308, and an inner angled surface 310.

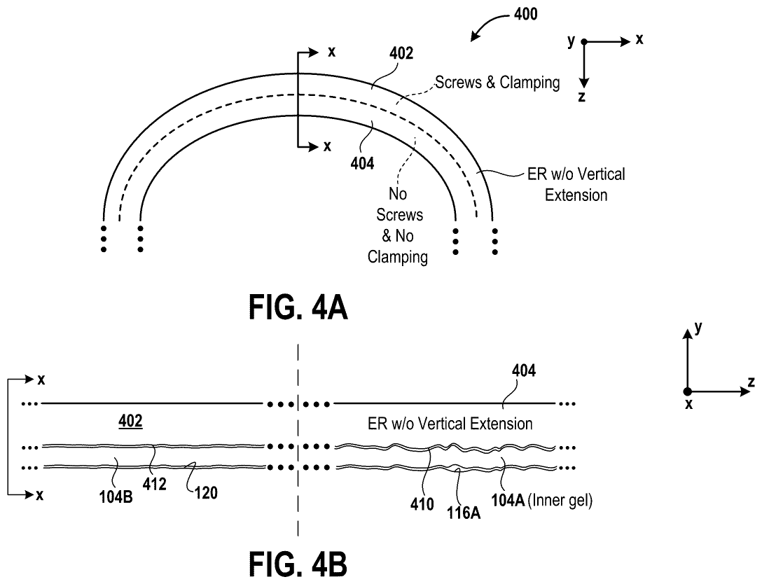

FIG. 4A is a top view of an edge ring 400 without a vertical extension, described herein. The edge ring 400 is split into a section 402 and another section 404 by dashed line. There are no screws within the section 404. Also, there is no clamping provided to the section 404. For example, there are no pull-down rods pulling down on the section 404. Rather, the screws are provided within the section 402 to attach the section 402 to the coupling ring 112 (FIG. 1).

FIG. 4B is a side view of an embodiment of the edge ring 400 taken along a section X-X of FIG. 4A. The section of the edge ring 400 is taken to illustrate that there are many discrepancies in contact between a bottom surface 410 of the section 404 and the inner gel 104A and between the outer top surface 116A of the substrate support 106 and the inner gel 104A when the vertical extension is not implemented. On the other hand, the screws increase contact between a bottom surface 412 of the section 402 and the outer gel 104B and between the top surface 120 of the coupling ring 112 and the outer gel 104B.

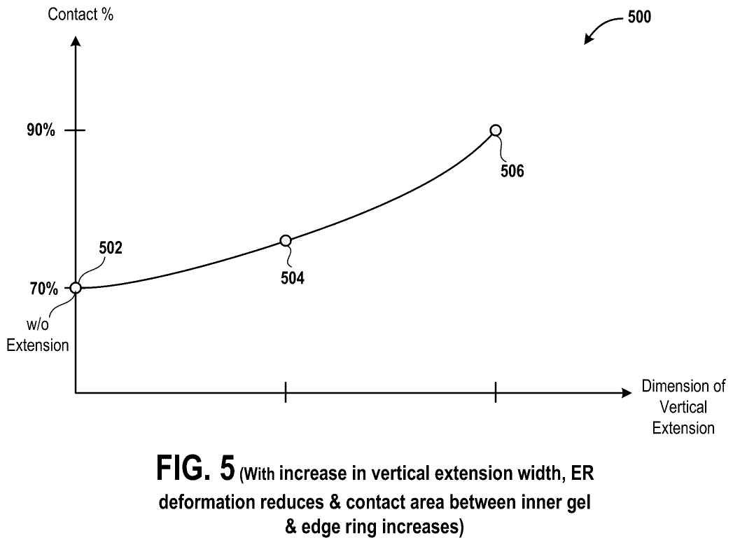

FIG. 5 is an embodiment of a graph 500 to illustrate a relationship between a percentage of contact area between the inner gel 104A and an edge ring, described herein, having a vertical extension compared to a relationship between a percentage of contact area between the inner gel 104A and the edge ring 400 (FIG. 4) without the vertical extension. The graph 500 plots a percentage of contact area between the inner gel 104A and an edge ring, provided herein, on a y-axis and a dimension, such as a height or a width or a combination of the weight and height, of the vertical extension on an x-axis. With an increase in the dimension of the vertical extension, there is an increase in a contact area between the edge ring having the vertical extension and the inner gel 104A. For example, as illustrated by points 502, 504, and 506 on the graph 500, the contact area between the inner gel 104A and the edge ring increases from 70% in case of the edge ring 400 having no vertical extension to 90% in case of the edge ring 200 (FIG. 2A).

Moreover, the graph 500 illustrates a percentage of contact area between the inner gel 104A and the outer top surface 116A of the substrate support 106 (FIG. 1). With the increase in the dimension of the vertical extension, the contact area between the inner gel 104A and the outer top surface 116A increases. For example, as illustrated by the points 502, 504, and 506 on the graph 500, the contact area between the inner gel 104A and the outer top surface 116A increases from 70% in case of the edge ring 400 having no vertical extension to 90% in case of the edge ring 200.

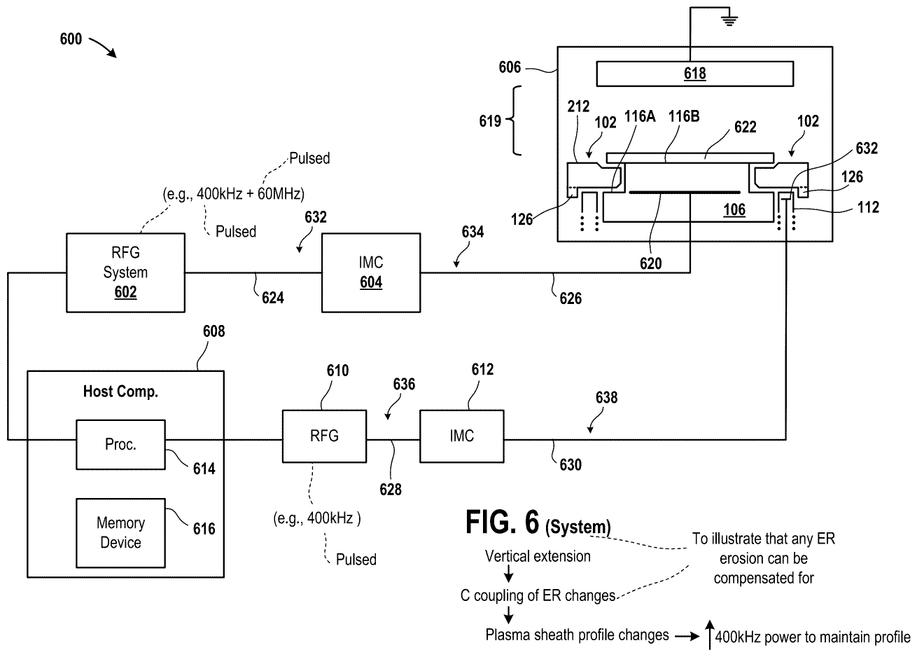

FIG. 6 is a diagram of an embodiment of a system 600 to illustrate that an effect on plasma by any possible erosion of the edge ring 102, described herein, having the vertical extension 126 can be compensated by controlling radio frequency (RF) power supplied to the edge ring 102. The system 600 includes an RF generator system 602, and impedance matching circuit (IMC) 604, a plasma chamber 606, a host computer 608, an RF generator 610, and another IMC 612.

An example of the RF generator system 602 includes one or more RF generators. To illustrate, the RF generator system 602 includes a first RF generator having a first operating frequency, a second RF generator having a second operating frequency, and a third RF generator having a third operating frequency. In the illustration, the second operating frequency is different from, such as greater than, the first operating frequency, and the third operating frequency is different from, such as greater than, the second operating frequency.

An example of the host computer 608 includes a desktop computer, a laptop computer, a controller, or a smart phone. An example of an impedance matching circuit, as described herein, include a network of circuit components, such as inductors and capacitors.

The host computer 608 includes a processor 614 and a memory device 616. Examples of the processor, as described herein, include a central processing unit (CPU), an application specific integrated circuit (ASIC), and a programmable logic device (PLD). The processor 614 is coupled to the memory device 616. Examples of a memory device, as used during, include a read-only memory (ROM) and a random-access memory (RAM).

The plasma chamber 606 includes an upper electrode 618, the substrate support 106, the coupling ring 112, and the edge ring 102. The upper electrode 618 is sometimes referred to herein as a top electrode and is coupled to a reference potential, such as a ground potential. The edge ring 102 surrounds the substrate support 106. The upper electrode 618 is located above the substrate support 106 to face a top surface of the substrate support 106 and the outer top surface 212 of the edge ring 102. A plasma region 619, which is a gap, is formed between the substrate support 102 and the upper electrode 618. A top surface of the edge ring 102 faces, such as is exposed to, the plasma region 619. A lower electrode 620 is embedded within the substrate support 106. A substrate 622 is placed on top of the inner top surface 116B of the substrate support 106. An example of the substrate 622 includes a semiconductor wafer.

The processor 614 is coupled to the RF generator system 602 and to the RF generator 610. The RF generator system 602 is coupled via an RF cable system 624 to one or more inputs of the IMC 604. For example, the first RF generator is coupled via a first RF cable to a first input of the IMC 614, the second RF generator is coupled via a second RF cable to a second input of the IMC 614, and the third RF generator is coupled via a third RF cable to a third input of the IMC 614. Moreover, an output of the IMC 614 is coupled to the lower electrode 620 via an RF transmission line 626. The RF generator 610 is coupled to an input of the IMC 612 via an RF cable 628. An output of the IMC 612 is coupled via an RF transmission line 630 to an electrode 632 within the coupling ring 112.

After receiving one or more recipes for generating one or more RF signals 632 from the processor 614, the RF generator system 602 generates the one or more RF signals 632 and sends the one or more RF signals 632 via the RF cable system 624 to the IMC 604. For example, the first RF generator generates a first RF signal and sends the first RF signal via the first RF cable to the IMC 604, the second RF generator generates a second RF signal and sends the second RF signal via the second RF cable to the IMC 604, and the third RF generator generates a third RF signal and sends the third RF signal via the third RF cable to the IMC 604.

The IMC 604 matches an impedance of a load coupled to the output of the IMC 604 with an impedance of a source coupled to the one or more inputs of the IMC 604 to modify an impedance of the one or more RF signals 632 to provide a modified RF signal 634 at the output of the IMC 604. An example of the source coupled to the one or more inputs of the IMC 604 is the RF generator system 602 and the RF cable system 624. An example of the load coupled to the output of the IMC 604 is the RF transmission line 626 and the plasma chamber 606. The modified RF signal 634 is transferred via the RF transmission line 626 to the lower electrode 620.

Similarly, after receiving a recipe for generating an RF signal 636 from the processor 614, the RF generator 610 generates the RF signal 636 and sends the RF signal 636 via the RF cable 628 to the input of the IMC 612. The IMC 612 matches an impedance of a load coupled to the output of the IMC 612 with an impedance of a source coupled to the input of the IMC 612 to modify an impedance of the RF signal 636 to provide a modified RF signal 638 at the output of the IMC 612. An example of the source coupled to the input of the IMC 612 is the RF generator 610 and the RF cable 628. An example of the load coupled to the output of the IMC 612 is the RF transmission line 630 and the plasma chamber 606. The modified RF signal 638 is transferred via the RF transmission line 630 to the electrode 632.

In addition to supplying the modified RF signals 634 and 638, one or more process gases are supplied to the plasma chamber 606. An example of a process gases includes an oxygen-containing gas, such as O₂. Another example of a process gas includes a fluorine-containing gas, e.g., tetrafluoromethane (CF₄), sulfur hexafluoride (SF₆), hexafluoroethane (C₂F₆), etc. When the modified RF signals 634 and 638, and the one or more process gases are supplied to the plasma chamber 606, plasma is stricken or maintained within the plasma region 619 of the plasma chamber 606. The plasma is used to process the substrate 622. For example, the plasma is used to deposit materials on the substrate 622 or to etch the substrate 622 or to clean the substrate 622.

With the inclusion of the vertical extension 126, a capacitance of the edge ring 102 changes. With the change in the capacitance, a capacitive coupling between the electrode 632 and the edge ring 212 and between the edge ring 212 and the upper electrode 618 changes. With the changes in the capacitive couplings, there is a change in a profile of a bottom plasma sheath near the edge ring 212. By supplying the modified RF signal 638 and controlling RF power of the RF signal 638, the profile can be adjusted to achieve uniformity in processing the substrate 622 or in processing multiple substrates within the plasma chamber 606.

In an embodiment, the RF cable 628 is coupled to the edge ring 212 instead of being coupled to the electrode 632 to provide power to the edge ring 212.

In one embodiment, instead of coupling the upper electrode 618 to the reference potential, the upper electrode 618 is supplied with RF power of an RF signal.

In one embodiment, any of the edge rings 226 (FIGS. 2B), 250 (FIG. 2C), and 276 (FIG. 2D) is used in place of the edge ring 102 in the system 600.

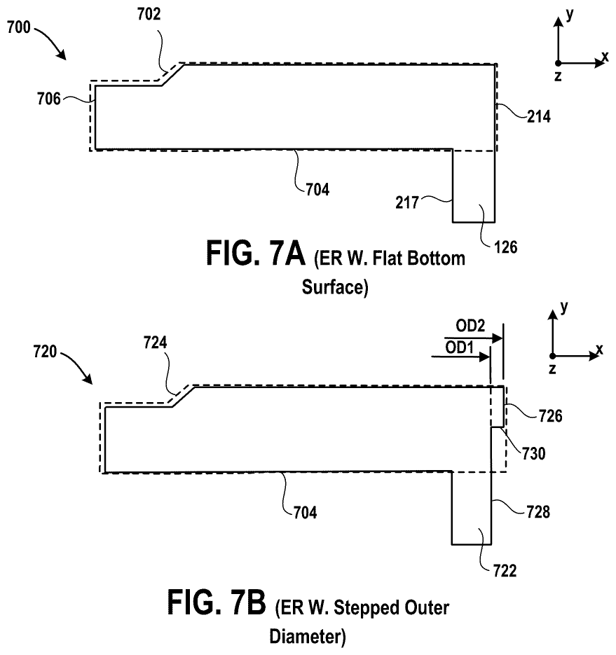

FIG. 7A is a diagram of an embodiment of another edge ring 700 having the vertical extension 126. The edge ring 700 has a main body 702 and the vertical extension 126. The vertical extension 126 extends vertically downward, in the −y direction, from the main body 702. The edge ring 700 has the same structure and function as the edge ring 102 (FIG. 1) except that the edge ring 150 has a bottom surface 704 that is flat and extends in a horizontal plane, along the x-axis, from an inner surface 706 of the edge ring 700 to the outer inner surface 217 of the edge ring 700. Also, the bottom surface 704 is adjacent to the inner surface 706, which is vertically oriented to extend along the y-axis with respect to the bottom surface 704. The edge ring 700 is used in place of the edge ring 102 in the system 100 of FIG. 1 and in the system 600 (FIG. 6).

In one embodiment, the bottom surface 704 has one or more grooves to accommodate respective one or more vacuum seals between the bottom surface 704 and the outer top surface 116A (FIG. 1) of the substrate support 106.

FIG. 7B is a diagram of an embodiment of another edge ring 720 having a vertical extension 722 and a main body 724. The vertical extension 722 extends vertically downward, in the −y direction, from the main body 724. The main body 724 has the same shape as that of the main body 702 (FIG. 7A) except that the main body 724 has a stepped outer diameter OD1. For example, instead of the outer surface 214 (FIG. 2A7A), the edge ring 720 has a top outer surface 726 having an outer diameter OD2 and a bottom outer surface 728 having the outer diameter OD1. An outer diameter, as described herein, of an edge ring is measured from a centroid of the edge ring. The top outer surface 726 hangs over the bottom outer surface 728. For example, the top outer surface 726 forms an outer diameter OD2 of the edge ring 720 and the bottom outer surface 728 forms the outer diameter OD1 of the edge ring 720. The outer diameter OD1 is less than the outer diameter OD2. A step 730, extending in the horizontal direction along the x-axis, is formed between the surfaces 726 and 728. Because of the step 730, the edge ring 720 has a T-shape as viewed in a direction of the z-axis.

A top portion of the bottom outer surface 728 forms a part of the main body 724 and a bottom portion of the bottom outer surface 728 forms a part of the vertical extension 722. Also, the vertical extension 722 is narrower, along the x-axis, than the vertical extension 126 (FIG. 7A). The edge ring 720 is used in place of the edge ring 102 in the system 100 of FIG. 1 and in the system 600 (FIG. 6).

Broadly speaking, in a variety of embodiments, the controller is defined as electronics having various integrated circuits, logic, memory, and/or software that receive instructions, issue instructions, control operation, enable cleaning operations, enable endpoint measurements, and the like. The integrated circuits include chips in the form of firmware that store program instructions, digital signal processors (DSPs), chips defined as ASICs, PLDs, and/or one or more microprocessors, or microcontrollers that execute program instructions (e.g., software). The program instructions are instructions communicated to the controller in the form of various individual settings (or program files), defining the parameters, the factors, the variables, etc., for carrying out a particular process on or for a semiconductor wafer or to a system. The program instructions are, in some embodiments, a part of a recipe defined by process engineers to accomplish one or more processing steps during the fabrication of one or more layers, materials, metals, oxides, silicon, silicon dioxide, surfaces, circuits, and/or dies of a wafer.

Without limitation, in various embodiments, example systems to which the methods are applied include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that is associated or used in the fabrication and/or manufacturing of semiconductor wafers.

It is further noted that in some embodiments, the above-described operations apply to several types of plasma chambers, e.g., a plasma chamber including an inductively coupled plasma (ICP) reactor, a transformer coupled plasma chamber, conductor tools, dielectric tools, a plasma chamber including an electron cyclotron resonance (ECR) reactor, etc. For example, one or more RF generators are coupled to an inductor within the ICP reactor. Examples of a shape of the inductor include a solenoid, a dome-shaped coil, a flat-shaped coil, etc.

Some of the embodiments also relate to a hardware unit or an apparatus for performing these operations. The apparatus is specially constructed for a special purpose computer. When defined as a special purpose computer, the computer performs other processing, program execution or routines that are not part of the special purpose, while still being capable of operating for the special purpose.

One or more embodiments can also be fabricated as computer-readable code on a non-transitory computer-readable medium. The non-transitory computer-readable medium is any data storage hardware unit, e.g., a memory device, etc., that stores data, which is thereafter be read by a computer system. Examples of the non-transitory computer-readable medium include hard drives, network attached storage (NAS), ROM, RAM, compact disc-ROMs (CD-ROMs), CD-recordables (CD-Rs), CD-rewritables (CD-RWs), magnetic tapes and other optical and non-optical data storage hardware units. In some embodiments, the non-transitory computer-readable medium includes a computer-readable tangible medium distributed over a network-coupled computer system so that the computer-readable code is stored and executed in a distributed fashion.

Although the method operations above were described in a specific order, it should be understood that in various embodiments, other housekeeping operations are performed in between operations, or the method operations are adjusted so that they occur at slightly different times, or are distributed in a system which allows the occurrence of the method operations at various intervals, or are performed in a different order than that described above.

It should further be noted that in an embodiment, one or more features from any embodiment, described above, are combined with one or more features of any other embodiment, also described above, without departing from a scope described in various embodiments described in the present disclosure.

Although the foregoing embodiments have been described in some detail for purposes of clarity of understanding, it will be apparent that certain changes and modifications can be practiced within the scope of appended claims. Accordingly, the present embodiments are to be considered as illustrative and not restrictive, and the embodiments are not to be limited to the details given herein.

1. An edge ring for use in a plasma chamber, comprising:
a horizontal section having an inner diameter and an outer diameter, wherein the inner diameter is configured to surround a substrate receiving location of a substrate support, wherein the horizontal section has a top surface and a lower surface, wherein the top surface of the horizontal section is configured to face a plasma region of the plasma chamber, wherein the lower surface of horizontal section has an inner gel receiving section and an outer gel receiving section, wherein the inner gel receiving section is configured to be in thermal contact with the substrate support and the outer gel receiving section is configured to be in thermal contact with a coupling ring; and
a vertical extension extending from the horizontal section, wherein the vertical extension is oriented downward at the outer diameter of the horizontal section, wherein the vertical extension provides an anchor for reducing flex of the horizontal section when a thermal gel is placed at each of the inner gel receiving section and the outer receiving section.

2. The edge ring of claim 1, wherein the vertical extension provides the anchor when a clamping force is applied using the coupling ring, wherein the vertical extension is integrated formed with the horizontal section, wherein the coupling ring has an underside that is configured to be coupled to a plurality of pull-down rods, wherein the clamping force is applied by the pull-down rods to pull down on the coupling ring, and the clamping force causes a compression of the thermal gel.

3. The edge ring of claim 1, wherein the inner gel receiving section is located radially closer to the substrate support than the outer gel receiving section.

4. The edge ring of claim 1, wherein the vertical extension extends vertically downward from the horizontal section and has a width that is less than a width of the horizontal section.

5. The edge ring of claim 4, wherein the vertical extension has a height and a cross-sectional area, wherein the cross-sectional area ranges from 4 square millimeters to 36 square millimeters.

6. The edge ring of claim 1, wherein the vertical extension does not add to a width of the horizontal section.

7. The edge ring of claim 1, wherein the vertical extension has a first bottom surface and the horizontal section has a second bottom surface, wherein the first bottom surface is at a level lower than a level of a second bottom surface.

8. The edge ring of claim 1, wherein the vertical extension and the horizontal section together form an L shape.

9. The edge ring of claim 1, wherein the vertical extension and the horizontal section together form a T shape.

10. An edge ring comprising:
a main body having:
a top portion;
an inner portion contiguous with the top portion;
a bottom portion contiguous with the inner portion; and
a first outer surface contiguous with the top portion; and
a vertical extension having a second outer surface contiguous with the first outer surface, wherein the vertical extension has an annular shape extending from a level of the bottom portion to a pre-determined level located below the level of the bottom portion, wherein the vertical extension extends to the pre-determined level at an outer diameter of the top portion.

11. The edge ring of claim 9, wherein the vertical extension is configured to extend into a gap formed within a barrier ring.

12. The edge ring of claim 10, wherein the vertical extension has an outer inner surface, an outer bottom surface contiguous with the outer inner surface, wherein the second outer surface is contiguous with the outer bottom surface.

13. The edge ring of claim 12, wherein the outer inner surface is vertically oriented, the outer bottom surface is horizontally oriented, and the second outer surface is vertically oriented.

14. The edge ring of claim 12, wherein the outer bottom surface is horizontally oriented, the outer inner surface is obliquely formed with respect to the outer bottom surface, and the second outer surface is obliquely formed with respect to the outer bottom surface.

15. The edge ring of claim 12, wherein the top portion includes an inner top surface and an outer top surface, and a top angled surface angled with respect to each of the inner and outer top surfaces, wherein the top angled surface provides an upward transition from the inner top surface to the outer top surface.

16. The edge ring of claim 15, wherein the inner portion includes an inner surface and an inner angled surface that forms an angle with respect to the inner surface, wherein the inner surface is located contiguous with the inner top surface of the top portion.

17. A plasma chamber comprising:
a top electrode;
an electrostatic chuck (ESC) located below the top electrode to form a plasma region therebetween, wherein the ESC has a top portion and a bottom portion;
an edge ring located besides the ESC; and
a coupling ring located below the edge ring,
wherein the edge ring includes:
a horizontal section having an inner diameter and an outer diameter, the inner diameter is configured to surround the top portion of the ESC, wherein the horizontal section has a top surface and a lower surface, wherein the lower surface of horizontal section has an inner gel receiving section and an outer gel receiving section, wherein the inner gel receiving section is configured to be in thermal contact with the ESC and the outer gel receiving section is configured to be in thermal contact with the coupling ring; and
a vertical extension being extending from the horizontal section, wherein the vertical extension is oriented downward at the outer diameter of the horizontal section, wherein the vertical extension provides an anchor for reducing flex of the horizontal section when a thermal gel is placed at each of the inner gel receiving section and the outer receiving section.

18. The plasma chamber of claim 17, wherein the vertical extension provides the anchor when a clamping force is applied using the coupling ring, wherein the coupling ring has an underside that is configured to be coupled to a plurality of pull-down rods, wherein the clamping force is applied by the pull-down rods to pull down on the coupling ring, and the clamping force causes a compression of the thermal gel.

19. The plasma chamber of claim 17, wherein the inner gel receiving section is located radially closer to the substrate support than the outer gel receiving section.

20. The plasma chamber of claim 17, wherein the vertical extension extends vertically downward from the horizontal section and has a width that is less than a width of the horizontal section.
